(19) United States
(12) Patent Application Publication
(10) Pub. No.: US 2013/0115778 A1
(43) Pub. Date: May 9, 2013

(54) Dry Etch Processes

(71) Applicants: Jun Xue, San Jose, CA (US); Jie Liu, Sunnyvale, CA (US); Yongmei Chen, San Jose, CA (US); Timothy Michaelson, Milpitas, CA (US); Paul Deaton, San Jose, CA (US); Timothy W. Weidman, Sunnyvale, CA (US); Christopher S. Ngai, Burlingame, CA (US)

(72) Inventors: Jun Xue, San Jose, CA (US); Jie Liu, Sunnyvale, CA (US); Yongmei Chen, San Jose, CA (US); Timothy Michaelson, Milpitas, CA (US); Paul Deaton, San Jose, CA (US); Timothy W. Weidman, Sunnyvale, CA (US); Christopher S. Ngai, Burlingame, CA (US)

(73) Assignee: Applied Materials, Inc., Santa Clara, CA (US)

(21) Appl. No.: 13/591,915

(22) Filed: Aug. 22, 2012

Related U.S. Application Data
(63) Continuation-in-part of application No. 13/289,657, filed on Nov. 4, 2011.

(51) Int. Cl. H01L 21/311; H01L 21/3065

(52) U.S. Cl. 438/703; 438/710; 438/694; 257/E21.218; 257/E21.252

(57) ABSTRACT

Provided methods of etching and/or patterning films. Certain methods comprise exposing at least part of a film on a substrate, the film comprising one or more of HfO₂, HfBₓO_{y}, ZrO₂, ZrBₓO_{y}, to a plasma comprising BCl₃ and argon to etch away said at least part of the film. Certain other methods relate to patterning substrates using said methods of etching films.

### CROSS-REFERENCE PARAGRAPH

This application is a continuation-in-part of U.S. patent application Ser. No. 13/289,657, filed Nov. 4, 2011, which is herein incorporated by reference in its entirety.

### TECHNICAL FIELD

Embodiments of the present invention generally relate to the methods comprising dry etching films.

### BACKGROUND

Deposition of thin films on a substrate surface is an important process in a variety of industries including semiconductor processing, diffusion barrier coatings and dielectrics for magnetic read/write heads. In the semiconductor industry, in particular, miniaturization requires a level control of thin film deposition to produce conformal coatings on high aspect ratio structures. One method for deposition of thin films with such control and conformal deposition is atomic layer deposition (ALD).

One useful application of ALD processes relates to self-aligned multiple patterning techniques. One example of such a process is self-aligned double patterning processes. A sidewall spacer is a conformal film layer formed on the sidewall of a pre-patterned feature. A spacer can be formed by conformal ALD of a film on a previously patterned feature, followed by anisotropic etching to remove all the film material on the horizontal surfaces, leaving only the material on the sidewalls. By removing the original patterned feature, only the spacer is left. However, since there are two spacers for every line, the line density becomes doubled. The spacer technique is applicable for defining narrow gates at half the original lithographic pitch, for example. There are also other related patterning processes, including self-aligned quad patterning techniques.

Methodology exists for the low temperature ALD of SiO₂ based films over photoresists for use as the spacer layers for self-aligned double patterning (SADP). Such process flows are poorly suited to applications in which SiO₂-based films are also present as underlayers in the stack being patterned, as there will be insufficient etch selectivity. Common SiO₂ based underlayers include such films as spin-on siloxane based layers useful as antireflection coatings underneath a photoresist, or SiON layers, for example dielectric anti-reflective coating (DARC). Dielectric anti-reflective coating is a dielectric material that limits reflections from a substrate during photolithography steps, which would otherwise interfere with the patterning process. Thus, there is a need for low temperature ALD films and methods of etching such films, which exhibit high dry etch selectivity relative to SiO₂-based films., as well as other such films where dry etch selectivity is desired.

### SUMMARY

One aspect is directed to a method of etching a film on a substrate. The method comprises exposing at least part of a film on a substrate, the film comprising one or more of HfO₂, HfBₓO_{y}, ZrO₂, ZrBₓO_{y}, to a plasma comprising BCl₃ and argon to etch away said at least part of the film. Various embodiments are listed below. It will be understood that the embodiments listed below may be combined not only as listed below, but in other suitable combinations in accordance with the scope of the invention.

In one or more embodiments, the substrate has a temperature of about 20 to about 200° C. during exposure of the substrate to the plasma. In some embodiments, the argon is flowed at a rate of about 200 sccm. In one or more embodiments, the BCl₃ is flowed at a rate ranging from about 50 sccm to about 150 sccm.

In some embodiments, said at least part of the film is etched at a rate of from about 400 A/min to about 700 A/min. In one or more embodiments, the plasma is generated at a power of about 300 W to about 1500 W. In further embodiments, the substrate has a wafer bias power of from about 50 to about 200 W. In some embodiments, said at least part of the film is exposed to the Ar and BCl₃ simultaneously.

In one or more embodiments, the method further comprises exposing said at least part of the film to Cl₂. In some embodiments, the method occurs in a chamber, and the chamber has a pressure of about 5 mTorr to about 20 mTorr.

A second aspect of the invention relates to a method of patterning a substrate. The method comprises depositing a film comprising hafnium or zirconium on a patterned layer on a substrate; anisotropically etching the film comprising hafnium or zirconium to partially expose the patterned layer, wherein anisotropically etching the film comprises exposing at least part of the film on a substrate to a plasma comprising BCl₃ and argon; plasma etching the patterned layer to substantially remove the patterned layer from the substrate and provide spacers comprising the film; patterning the substrate using the spacers to provide a patterned substrate; and substantially removing the spacers.

In one or more embodiments of this aspect, the film comprises HfO₂, HfBₓO_{y}, ZrO₂ or ZrBₓO_{y}. In some embodiments, the patterned layer is a patterned photoresist. In one or more embodiments, plasma etching the patterned photoresist comprises exposing the patterned photoresist to a second plasma comprising oxygen.

In some embodiments, the spacers are removed using dilute HF or a dry strip process. In one or more embodiments, the substrate comprises a dielectric anti-reflection coating.

In one or more variants of the invention, the substrate has a temperature of about 10 to about 200° C. during the anisotropic etch. In some embodiments, the plasma is flowed at a rate ranging from about 50 sccm to about 150 sccm and the second plasma is flowed at a rate of about 200 sccm.

A third aspect of the invention relates to a method of patterning a substrate. The method comprises forming a patterned photoresist on a substrate, wherein the substrate comprises silicon, an underlayer comprising a carbon-based polymeric layer or an amorphous carbon-based layer on the silicon, and a dielectric anti-reflective coating on the underlayer; depositing a film comprising HfO₂, HfBₓO_{y}, ZrO₂ or ZrBₓO_{y} on the patterned photo resist and substrate; anisotropically etching the film comprising hafnium or zirconium to partially expose the patterned photoresist, wherein anisotropically etching the film comprises exposing at least part of the film on a substrate to a plasma comprising BCl₃ and argon, and wherein the substrate has a temperature of about 20 to about 200° C. during the anisotropic etch; plasma etching the patterned photoresist to substantially remove the patterned photo resist from the substrate and exposing more of the dielectric anti-reflective coating, and to provide spacers comprising the film; removing the exposed parts of the dielectric anti-reflective coating to expose at least a part of the underlayer and provide dielectric anti-reflective coating only under the spacers; removing the exposed part of the underlayer to expose at least a portion of the substrate and provide underlayer only under the spacers and dielectric anti-reflective coating; and removing the spacers comprising the film. In one embodiment, the method further comprises patterning the exposed substrate.

### BRIEF DESCRIPTION OF THE DRAWINGS

FIGS. 1A-G are an illustration of a self-aligned double patterning process using an etching method in accordance with an embodiment of the invention;

FIG. 2 is a scanning electron microscope image of a HfBₓO_{y} film deposited over a film stack;

FIG. 3 is a scanning electron microscope image after anisotropically etching a HfBₓO_{y} film according to one or more embodiments of the invention to form spacers;

FIG. 4 is a scanning electron microscope after stripping photoresist cores according to one or more embodiments of the invention;

FIG. 5 is a scanning electron microscope after opening a dielectric antireflection coating using HfBₓO_{y} spacers according to one or more embodiments of the invention; and

FIG. 6 is a scanning electron microscope after etching an Advanced Patterning Film™ using HfBₓO_{y} spacers according to one or more embodiments of the invention.

### DETAILED DESCRIPTION

Before describing several exemplary embodiments of the invention, it is to be understood that the invention is not limited to the details of construction or process steps set forth in the following description. The invention is capable of other embodiments and of being practiced or being carried out in various ways.

One or more aspects of the invention relate to etching processes and films which allow for high etch selectivity. For example, hafnium boron oxide hardmask (HfBₓO_{y}) is resistant to a wide variety of etch chemistries, but is etched by one or more of the methods described herein, which will leave other substrates intact. Thus, the hardmask may be etched without disturbing other layers, and vice versa. Furthermore, such films are easily stripped using conventional methods, such as dilute HF or dry etching methods (in embodiments where wet strip is incompatible with the substrate), once underlying substrates are patterned.

### Etch Process

One aspect of the invention relates to a method of etching a film on a substrate. The method comprises exposing at least part of a film on a substrate, the film comprising one or more of HfO₂, HfBₓO_{y}, ZrO₂, ZrBₓO_{y}, to a plasma comprising BCl₃ and argon to etch away said at least part of the film.

A “substrate” as used herein, refers to any substrate or material surface formed on a substrate upon which film processing is performed during a fabrication process. For example, a substrate surface on which processing can be performed includes materials such as silicon, silicon oxide, strained silicon, silicon on insulator (SOI), carbon doped silicon oxides, silicon nitride, doped silicon, germanium, gallium arsenide, glass, sapphire, and any other materials such as metals, metal nitrides, metal alloys, and other conductive materials, depending on the application. In one or more embodiments, the substrate comprises Applied Materials Advanced Patterning Film™ (APF®) layers, which comprise an amorphous carbon hardmask, and can be produced in an APF® chamber on the Producer® system, available from Applied Materials, Inc. Substrates include, without limitation, semiconductor wafers. Substrates may be exposed to a pretreatment process to polish, etch, reduce, oxidize, hydroxylate, anneal and/or bake the substrate surface. In addition to film processing directly on the surface of the substrate itself, in the present invention any of the film processing steps disclosed may also be performed on an underlayer formed on the substrate as disclosed in more detail below, and the term “substrate surface” is intended to include such underlayer as the context indicates. Thus, for example, the term “substrate” may comprise more than one layer (i.e., silicon, an Advanced Patterning Film^{Tm} layer, and/or a DARC layer).

The term “HfBOₓ” refers to a film containing hafnium, boron and oxygen. This term may be used interchangeably with HfBₓO_{y}. The film optionally contains hydrogen. Where the film contains hydrogen, the film may also be represented by the formula HfBₓO_{y}H_{z}. Similarly, the term “ZrBOₓ” refers to a film containing zirconium, boron and oxygen. This term may be used interchangeably with ZrBₓO_{y}. The film optionally contains hydrogen. Where the film contains hydrogen, the film may also be represented by the formula ZrBₓO_{y}H_{z}. The variable x may have a value of from about 0 to about 4, and in a specific embodiment, a value of about 2. The variable y may have a value of from about 0 to about 10, and in a specific embodiment, about 2 to 10. In an alternative embodiment, y may have a value of about 0 to about 8, and in a specific embodiment, a value of about 0 to about 6. Finally, the variable z may have a range of from about 0 to about 10, and in a specific embodiment, about 4. In an alternative embodiment, the film comprises zirconium, boron and oxygen. Co-reactants and process conditions may be selected to tune composition of the film, particularly the boron content.

In one or more embodiments, the etch process described herein is a dry etch process. In one or more embodiments, at least part of the film is exposed to the Ar and BCl₃ simultaneously or substantially simultaneously. As used herein, “substantially simultaneously” refers to either co-flow or where there is merely overlap between exposures of the two components. Process conditions, such as wafer temperature, plasma power, wafer bias power and chamber pressures may be varied.

The processes described herein allow for relatively low-temperature etch. Thus in one or more embodiments, the wafer temperature may range from about 10 to about 200° C. In further embodiments, the wafer may have a temperature ranging from about 10, 15, or 20° C. to about 30, 40, 50, 80, 100, 150 or 200° C. Such relatively low temperature ranges are advantageous, as they tend to result in less substrate damage and can accommodate materials or patterned features that are temperature intolerant.

In one or more embodiments, the use of plasma provides sufficient energy to promote a species into the excited state where surface reactions become favorable and likely. Introducing the plasma into the process can be continuous or pulsed. In some embodiments, the reagents may be ionized either locally (i.e., within the processing area) or remotely (i.e., outside the processing area). In some embodiments, remote ionization can occur upstream of the deposition chamber such that ions or other energetic or light emitting species are not in direct contact with the depositing film. In some process embodiments, the plasma is generated external from the processing chamber, such as by a remote plasma generator system. The plasma may be generated via any suitable plasma generation process or technique known to those skilled in the art. For example, plasma may be generated by one or more of a microwave (MW) frequency generator or a radio frequency (RF) generator. The frequency of the plasma may be tuned depending on the specific reactive species being used. Suitable frequencies include, but are not limited to, 2 MHz, 13.56 MHz, 40 MHz, 60 MHz and 100 MHz. In one or more embodiments, the plasma source is an inductively coupled plasma source. In some embodiments, the plasma power is less than about 1000 W. Alternatively, in one or more embodiments, the plasma is generated at a power of about 300 W to about 1500 W.

In one or more embodiments, the substrate has a wafer bias power. Thus, for example, power (e.g., 13.5 MHz RF power) may be applied to an electrostatic chuck to control ion bombardment for embodiments relating to anisotropic etch. In some embodiments, the wafer or substrate may sit on an electrostatic chuck during processing. In one or more embodiments, the wafer bias power is less than about 200 W. In further embodiments, the wafer bias power ranges from about 50, 75 or 100 to about 150 or 200 W.

The flow rate of the gases may be varied. In one or more embodiments, the argon is flowed at a rate of about 50 sccm to about 500 sccm. In some embodiments, the flow rate is about 50 to about 400, 75 to about 350, 100 to about 300 sccm. In one or more embodiments, the flow rate is about 50, 100, 150, 200, 250, 300, 350 or 400 sccm. In one or more embodiments, the BCl₃ is flowed at a rate of about 50 to about 200 sccm. In some embodiments, the flow rate is about 50 to about 175, 75 to about 150, 100 to about 125 sccm. In one or more embodiments, the flow rate is about 50, 60, 70, 80, 90, 100, 110, 120, 130, 140, 150, 160, 170, 180, 190 or 200 sccm.

In one or more embodiments where the etch process is carried out in a chamber, the chamber pressure ranges from about 5 mTorr to about 20 mTorr. In further embodiments, the chamber pressure is 10 mTorr.

The etch rate of the processes described herein will generally range from about 400 A/min to about 1000 A/min. In further embodiments, the etch rate ranges from about 400 to about 900, 500 to about 800, or 600 to about 700 A/min. In some embodiments, the etch rate is from about 400, 450, 500, 550 to about 600, 650, 700, 750, 800, 900, 1000 A/min. The etch rate can be controlled by changes various aspects of the process. For example, a higher temperature will generally enhance the etch rate. Additionally, higher plasma powers will also generally increase the etch rate. The etch rate may be further enhanced by adding certain components to the etch recipe. For example, in one or more embodiments, Cl₂ may also be flowed. In further embodiments, Cl₂ gas is added to the plasma comprising Ar and BCl₃. In yet further embodiments, the Cl₂ gas is flowed at a rate of about 50 sccm to about 150 sccm. In one or more embodiments, the plasma comprises 5% by volume Cl₂. In such embodiments, the etch rate may be increased by as much as 30%.

The etch methods described herein may have utility as part of other processes. Such processes include self aligned multiple patterning, self aligned double patterning (SADP), self aligned quadruple patterning (SAQP) processes and tone reversal processes. The etch may be either isotropic or anisotropic, according to the demands of the particular application.

### Patterning Processes

In one or more embodiments, the etch methods constitute the anisotropic etch portion of a patterning process. Accordingly, another aspect of the invention relates to a method of patterning a substrate. The method comprises depositing a film comprising hafnium or zirconium on a patterned layer on a substrate; anisotropically etching the film comprising hafnium or zirconium to partially expose the patterned layer, wherein anisotropically etching the film comprises exposing at least part of the film on a substrate to a plasma comprising BCl₃ and argon; plasma etching the patterned layer to substantially remove the patterned layer from the substrate and provide spacers comprising the film; patterning the substrate using the spacers to provide a patterned substrate; and substantially removing the spacers. In some embodiments, the patterned layer is any layer that exhibits good etch selectivity with compared to the spacer material. In some embodiments the patterned layer includes but is not limited to APF® layers, oxides and nitrides. In one or more embodiments, the patterned layer is a photoresist.

In one or more embodiments, the film comprising hafnium or zirconium is utilized as a blanket hardmask. In such embodiments, the film is deposited on a nominally (although not necessarily) flat substrate, patterned. The film is then used as an etch mask to transfer the pattern into the substrate below.

The deposition of films comprising HfO₂ or ZrO₂ is well known in the art. HfBₓO_{y} and ZrBₓO_{y} films may be deposited by sequentially exposing a substrate surface to alternating flows of a M(BH₄)₄ precursor and a co-reactant to provide a film. M is a metal selected from hafnium and zirconium. In some embodiments, the substrate surface may be exposed to the reactants co-reactants such that the substrate surface does not become fully saturated.

As used herein, the phrase “atomic layer deposition” is used interchangeably with “ALD,” and refers to a process which involves sequential exposures of chemical reactants, and each reactant is deposited from the other separated in time and space. In ALD, chemical reactions take place only on the surface of the substrate in a stepwise fashion. However, according to one or more embodiments, the phrase “atomic layer deposition” is not necessarily limited to reactions in which each reactant layer deposited is limited to a monolayer (i.e., a layer that is one reactant molecule thick). The precursors in accordance with various embodiments of the invention will deposit conformal films regardless of whether only a single monolayer was deposited. Atomic layer deposition is distinguished from “chemical vapor deposition” or “CVD,” in that CVD refers to a process in which one or more reactants continuously form a film on a substrate by reaction in a process chamber containing the substrate or on the surface of the substrate. Such CVD processes tend to be less conformal than ALD processes.

The Hf(BH₄)₄ precursor is relatively volatile and reactive, which allows for the deposition of conformal hafnium-containing films at relatively low temperatures using a co-reactant. According to one or more embodiments, useful co-reactants include a source of oxygen. Examples of such co-reactants include, but are not limited to, water (H₂O), hydrogen peroxide (H₂O₂), ozone (O₃), mixtures of hydrogen peroxide and water (H₂O₂/H₂O), oxygen (O₂), mixtures of ozone and oxygen (O₃ in O₂) and other mixtures thereof. Use of these reactants produces a film comprising HfBOₓ.

In accordance with another embodiment, the co-reactant is ammonia (NH₃). Where M comprises hafnium, the film provided will comprise hafnium, boron and nitrogen. Alternatively, where M comprises zirconium, the film provided will comprise zirconium, boron and nitrogen.

In one method of synthesizing such M(BH₄)₄ precursors, HfCl₄ or ZrCl₄ is placed in an appropriate vessel (for example, a round bottom flask) and mixed with an excess of LiBH₄. A stir bar is added to the flask, and the mixture of two solids is stirred overnight. After stirring is completed, the product, also a white solid, can be optionally purified by sublimation and is transferred to an ampoule appropriate for delivery of the precursor to an ALD reactor.

Other co-reactants may be used to vary the elemental content of the film. For example, ammonia may be used as a co-reactant to obtain films of hafnium, boron and nitrogen. Similarly, the closely related and analogous precursor Zr(BH₄)₄ may be used to deposit zirconium films using the same set of co-reactants using an analogous ALD process to produce directly analogous films.

Another feature of the films deposited according to one or embodiments, is very efficient utilization and incorporation of the precursor into the films. The resulting growth rates are about 2.7 Angstroms per cycle. In a specific embodiment, deposition processes employ only M(BH₄)₄ with H₂O as the co-reactant, and are applicable directly over oxygen very oxygen sensitive underlayers and liberate only H₂ and potentially B₂H₆ as volatile byproducts.

In exemplary embodiment of an ALD process, a first chemical precursor (“A”) is pulsed, for example, Hf(BH₄)₄ to the substrate surface in a first half reaction. Excess unused reactants and the reaction by-products are removed, typically by an evacuation-pump down and/or by a flowing inert purge gas. Then a co-reactant “B”, for example an oxidant or ammonia, is delivered to the surface, wherein the previously reacted terminating substituents or ligands of the first half reaction are reacted with new ligands from the “B” co-reactant, creating an exchange by-product. In some embodiments, the “B” co-reactant also forms self saturating bonds with the underlying reactive species to provide another self-limiting and saturating second half reaction. In alternative embodiments, the “B” co-reactant does not saturate the underlying reactive species. A second purge period is typically utilized to remove unused reactants and the reaction by-products. The “A” precursor, “B” co-reactants and purge gases can then again be flowed. The alternating exposure of the surface to reactants “A” and “B” is continued until the desired thickness film is reached, which for most anticipated applications would be approximately in the range of 5 nm to 40 nm, and more specifically in the range of 10 and 30 nm (100 Angstroms to 300 Angstroms). It will be understood that the “A”, “B”, and purge gases can flow simultaneously, and the substrate and/or gas flow nozzle can oscillate such that the substrate is sequentially exposed to the A, purge, and B gases as desired.

The precursors and/or reactants may be in a state of gas, plasma, vapor or other state of matter useful for a vapor deposition process. During the purge, typically an inert gas is introduced into the processing chamber to purge the reaction zone or otherwise remove any residual reactive compound or by-products from the reaction zone. Alternatively, the purge gas may flow continuously throughout the deposition process so that only the purge gas flows during a time delay between pulses of precursor and co-reactants.

Thus, in one or more embodiments, alternating pulses or flows of “A” precursor and “B” co-reactant can be used to deposit a film, for example, in a pulsed delivery of multiple cycles of pulsed precursors and co-reactants, for example, A pulse, B co-reactant pulse, A precursor pulse, B co-reactant pulse, A precursor pulse, B co-reactant pulse, A precursor pulse, B co-reactant pulse. As noted above, instead of pulsing the reactants, the gases can flow simultaneously from a gas delivery head or nozzle and the substrate and/or gas delivery head can be moved such that the substrate is sequentially exposed to the gases.

Of course, the aforementioned ALD cycles are merely exemplary of a wide variety of ALD process cycles in which a deposited layer is formed by alternating layers of precursors and co-reactants.

A deposition gas or a process gas as used herein refers to a single gas, multiple gases, a gas containing a plasma, combinations of gas(es) and/or plasma(s). A deposition gas may contain at least one reactive compound for a vapor deposition process. The reactive compounds may be in a state of gas, plasma, vapor, during the vapor deposition process. Also, a process may contain a purge gas or a carrier gas and not contain a reactive compound.

The films in accordance with various embodiments of this invention can be deposited over virtually any substrate material. As the ALD processes described herein are relatively low-temperature, it is particularly advantageous to use these processes with substrates that are thermally unstable. A “substrate surface,” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, silicon nitride, doped silicon, germanium, gallium arsenide, glass, sapphire, and any other materials such as metals, metal nitrides, metal alloys, and other conductive materials, depending on the application. Barrier layers, metals or metal nitrides on a substrate surface include titanium, titanium nitride, tungsten nitride, tantalum and tantalum nitride, aluminum, copper, or any other conductor or conductive or non-conductive barrier layer useful for device fabrication. Substrates may have various dimensions, such as 200 mm or 300 mm diameter wafers, as well as, rectangular or square panes. Substrates on which embodiments of the invention may be useful include, but are not limited to semiconductor wafers, such as crystalline silicon (e.g., Si<100> or Si<111>), silicon oxide, strained silicon, silicon germanium, doped or undoped polysilicon, doped or undoped silicon wafers, III-V materials such as GaAs, GaN, InP, etc. and patterned or non-patterned wafers. Substrates may be exposed to a pretreatment process to polish, etch, reduce, oxidize, hydroxylate, anneal and/or bake the substrate surface.

The co-reactants are typically in vapor or gas form. The reactants may be delivered with a carrier gas. A carrier gas, a purge gas, a deposition gas, or other process gas may contain nitrogen, hydrogen, argon, neon, helium, or combinations thereof. Plasmas may be useful for depositing, forming, annealing, treating, or other processing of photoresist materials described herein. The various plasmas described herein, such as the nitrogen plasma or the inert gas plasma, may be ignited from and/or contain a plasma co-reactant gas.

In one or more embodiments, the various gases for the process may be pulsed into an inlet, through a gas channel, from various holes or outlets, and into a central channel. In one or more embodiments, the deposition gases may be sequentially pulsed to and through a showerhead. Alternatively, as described above, the gases can flow simultaneously through gas supply nozzle or head and the substrate and/or the gas supply head can be moved so that the substrate is sequentially exposed to the gases.

In another embodiment, a hafnium or zirconium containing film may be formed during plasma enhanced atomic layer deposition (PEALD) process that provides sequential pulses of a precursors and plasma. In specific embodiments, the co-reactant may involve a plasma. In other embodiments involving the use of plasma, during the plasma step the reagents are generally ionized during the process, though this might occur only upstream of the deposition chamber such that ions or other energetic or light emitting species are not in direct contact with the depositing film, this configuration often termed a remote plasma. Thus in this type of PEALD process, the plasma is generated external from the processing chamber, such as by a remote plasma generator system. During PEALD processes, a plasma may be generated from a microwave (MW) frequency generator or a radio frequency (RF) generator. Although plasmas may be used during the ALD processes disclosed herein, it should be noted that plasmas are not required. Indeed, other embodiments relate to ALD under very mild conditions without a plasma.

The ALD process provides that the processing chamber or the deposition chamber may be pressurized at a pressure within a range from about 0.01 Torr to about 100 Torr, for example from about 0.1 Torr to about 10 Torr, and more specifically, from about 0.5 Torr to about 5 Torr. Also, according to one or more embodiments, the chamber or the substrate may be heated such that deposition can take place at a temperature lower than about 200° C. In other embodiments, deposition may take place at temperatures lower than about 100° C., and in others, even as low as about room temperature. In one embodiment, deposition is carried out at a temperature range of about 50° C. to about 100° C. As used herein, “room temperature” refers to a temperature range of about 20 to about 25° C.

A substrate can be any type of substrate described above. An optional process step involves preparation of a substrate by treating the substrate with a plasma or other suitable surface treatment to provide active sites on the surface of the substrate. Examples of suitable active sites include, but are not limited to O—H, N—H, or S—H terminated surfaces. However it should be noted that this step is not required, and deposition according to various embodiments of the invention can be carried out without adding such active sites.

Delivery of “A” Precursor to Substrate Surface

The substrate can be exposed to the “A” precursor gas or vapor formed by passing a carrier gas (for example, nitrogen or argon) through an ampoule of the precursor, which may be in liquid form. The ampoule may be heated. The “A” precursor gas can be delivered at any suitable flow rate within a range from about 10 sccm to about 2,000 sccm, for example, from about 50 sccm to about 1,000 sccm, and in specific embodiments, from about 100 sccm to about 500 sccm, for example, about 200 sccm. The substrate may be exposed to the metal-containing “A” precursor gas for a time period within a range from about 0.1 seconds to about 10 seconds, for example, from about 1 second to about 5 seconds, and in a specific example, for approximately 2 seconds. The flow of the “A” precursor gas is stopped once the precursor has adsorbed onto all reactive surface moieties on the substrate surface. In an ideally behaved ALD process, the surface is readily saturated with the reactive precursor “A.”

First Purge

The substrate and chamber may be exposed to a purge step after stopping the flow of the “A” precursor gas. A purge gas may be administered into the processing chamber with a flow rate within a range from about 10 sccm to about 2,000 sccm, for example, from about 50 sccm to about 1,000 sccm, and in a specific example, from about 100 sccm to about 500 sccm, for example, about 200 sccm. The purge step removes any excess precursor, byproducts and other contaminants within the processing chamber. The purge step may be conducted for a time period within a range from about 0.1 seconds to about 8 seconds, for example, from about 1 second to about 5 seconds, and in a specific example, from about 4 seconds. The carrier gas, the purge gas, the deposition gas, or other process gas may contain nitrogen, hydrogen, argon, neon, helium, or combinations thereof. In one example, the carrier gas comprises nitrogen.

Delivery of “B” Co-reactant to Substrate Surface

After the first purge, the substrate active sites can be exposed a “B” co-reactant gas or vapor formed by passing a carrier gas (for example, nitrogen or argon) through an ampoule the “B” co-reactant. The ampoule may be heated. The “B” reactant gas can be delivered at any suitable flow rate within a range from about 10 sccm to about 2,000 sccm, for example, from about 50 sccm to about 1,000 sccm, and in specific embodiments, at about 200 sccm. The substrate may be exposed to the “B” reactant gas for a time period within a range from about 0.1 seconds to about 8 seconds, for example, from about 1 second to about 5 seconds, and in a specific example, for about 2 seconds. The flow of the “B” reactant gas may be stopped once “B” has adsorbed onto and reacted with readily “A” precursor deposited in the preceding step.

Second Purge

The substrate and chamber may be exposed to a purge step after stopping the flow of the “B” co-reactant gas. A purge gas may be administered into the processing chamber with a flow rate within a range from about 10 sccm to about 2,000 sccm, for example, from about 50 sccm to about 1,000 sccm, and in a specific example, from about 100 sccm to about 500 sccm, for example, about 200 sccm. The purge step removes any excess precursor, byproducts and other contaminants within the processing chamber. The purge step may be conducted for a time period within a range from about 0.1 seconds to about 8 seconds, for example, from about 1 second to about 5 seconds, and in a specific example, from about 4 seconds. The carrier gas, the purge gas, the deposition gas, or other process gas may contain nitrogen, hydrogen, argon, neon, helium, or combinations thereof. In one example, the carrier gas comprises nitrogen. The “B” co-reactant gas may also be in the form of a plasma generated remotely from the process chamber.

The hafnium and zirconium containing films can also be etch-resistant. In particular, HfBOₓ films exhibit high dry etch selectivity, particularly as compared to SiO₂-based films. Such films include spin-on siloxane based layers useful as antireflection coatings underneath a photoresist, or SiON layers, for example dielectric anti-reflective coating (DARC). As discussed above, SiO₂-based films cannot be used as underlayers for self-aligned double patterning approaches using low temperature ALD SiO₂ films, as they exhibit insufficient etch selectivity. Thus in one embodiment, the film is deposited onto a photoresist.

In certain embodiments, low temperature ALD of HfBOₓ films according to one or more embodiments described above is carried out over patterned photoresist films formed directly over the silicon-based dielectric layer. This allows for subsequent oxygen plasma strip steps to selectively remove the organic photoresist core layers without significant impact on the interface between the HfBOₓ film and the silicon-based dielectric film. Similarly, in certain embodiments, the photoresist pattern can be transferred through the underlying DARC hardmask film before the HfBOₓ ALD process to create nearly perfectly aligned complementary hardmask combinations. Thus, in one or more embodiments, the substrate comprises a dielectric anti-reflection coating.

One or more of the hafnium- and zirconium-containing films described herein may be deposited directly onto photoresist materials. Because in one or more embodiments deposition is carried out at low temperatures, there is little risk of damage to the photoresist material. As one or more embodiments of the etching methods described herein may also be carried out at relatively low temperatures, this further allows for little damage to any underlying materials.

Subsequent to depositing the hafnium- or zirconium-containing film on the photoresist, the film may be anisotropically etched. Any variations in the etch process described above may be applied when the etch is a part of a patterning process. Thus, for example, the film may comprise one or more of HfO₂, HfBₓO_{y}, ZrO₂ and ZrBₓO_{y}. In one or more embodiments, the substrate has a temperature of about 10 to about 200° C. during the anisotropic etch. In one or more embodiments, the plasma is flowed at a rate ranging from about 50 sccm to about 150 sccm and the second plasma is flowed at a rate of about 200 sccm.

In one or more embodiments, plasma etching the patterned photoresist comprises exposing the patterned photoresist to a second plasma comprising oxygen. In one or more embodiments, the spacers are removed using dilute HF or dry etch processes. In further embodiments, the spacers are stripped via a high temperature dry etch process. In one or more embodiments, the film can be stripped in acidic or basic solutions.

Core strip and transfer to the substrate are known generally in the art and vary greatly depending on substrate material and core material.

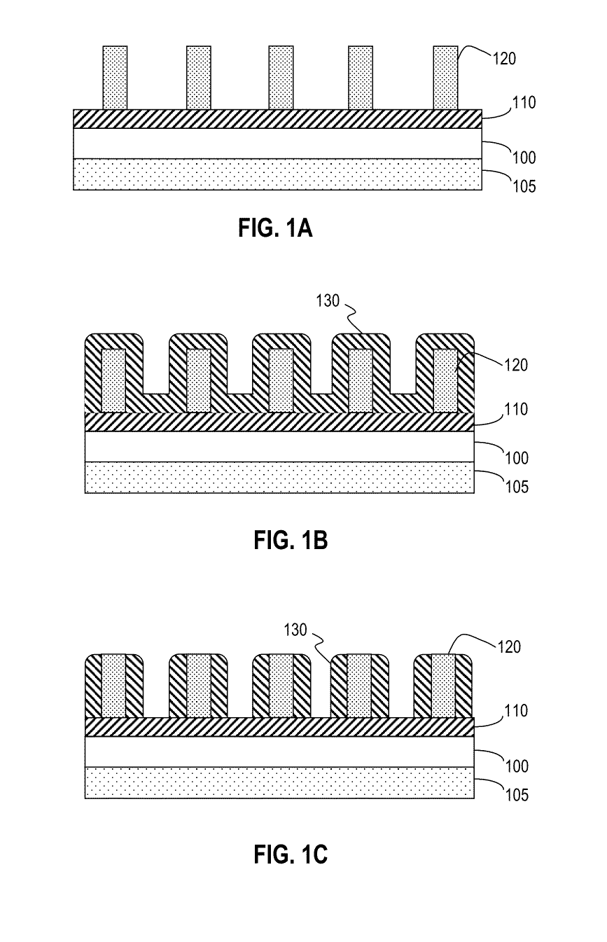

An exemplary and non-limiting self-aligned double patterning (SADP) process is shown in FIGS. 1A-F. Turning to FIG. 1A, a DARC layer 110 is overlaid onto an Advanced Patterning Film™ layer 100, which is overlaid on a silicon substrate 105. A photoresist is deposited onto the DARC layer 110 and patterned to provide patterned photoresist 120. The patterning of the photoresist is not shown. As shown in FIG. 1B, a spacer film 130 can be deposited in accordance with one or more embodiments described herein onto the patterned photoresist 120 and DARC layers 110. For example, spacer film 130 can be a HfBOₓ film deposited using a Hf(BH₄)₄ precursor and an oxidant co-reactant. In FIG. 1C, the spacer film 130 is anisotropically etched using one or more of the etching processes described herein to form spacers by removing spacer film 130 from horizontal surfaces. Turning to FIG. 1D, the original patterned photoresist 120 core is etched away, leaving only what is left of spacer film 130. Then DARC layer 110 can be patterned using the spacers as a guide, as shown in FIG. 1E. Following this, The APF® layer 100 may be etched, also using the spacers as a guide, to provide the patterned film shown in FIG. 1F. Because of the superior etch selectivity of the films and etch processes described herein, it is possible to etch away either the DARC layer 110 or APF® layer 100 without disturbing spacer film 130.

The remaining spacer film 130 can then be stripped via a wet clean process to provide the patterned DARC layer 110 and APF® layer 100, as shown in FIG. 1G. In one or more embodiments, DARC may be etched slowly in HF or other wet clean processes. In such embodiments, the Carina dry etch process (using Applied Materials' Centura Carina Etch system) may be used instead. The selectivity between the films described herein, such as HfBOₓ film, allows for this process to be carried out.

Accordingly, in one or more embodiments, the method comprises forming a patterned photoresist on a substrate, wherein the substrate comprises silicon, an underlayer comprising a carbon-based polymeric layer or an amorphous carbon-based layer on the silicon, and a dielectric anti-reflective coating on the underlayer; depositing a conformal film comprising HfO₂, HfBₓO_{y}, ZrO₂ or ZrBₓO_{y} on the patterned photoresist and substrate; anisotropically etching the film comprising hafnium to partially expose the patterned photoresist, wherein anisotropically etching the film comprises exposing at least part of the film on a substrate to a plasma comprising BCl₃ and argon; plasma etching the patterned photoresist to substantially remove the patterned photo resist from the substrate and exposing more of the dielectric anti-reflective coating, and to provide spacers comprising the film; removing the exposed parts of the dielectric anti-reflective coating to expose at least a part of the underlayer and provide dielectric anti-reflective coating only under the spacers; removing the exposed part of the underlayer to expose at least a portion of the substrate and provide underlayer only under the spacers and dielectric anti-reflective coating; and removing the spacers comprising the film. Again, any of the suitable variants described above may be applied to these embodiments. Thus, for example, in one or more embodiments, the method further comprises patterning the exposed substrate. In some embodiments, the substrate has a temperature of about 20 to about 200° C. during the isotropic etch, the first plasma is flowed at a rate ranging from about 50 sccm to about 150 sccm and the second plasma is flowed at a rate of about 200 sccm.

### Equipment

According to one or more embodiments, the substrate is subjected to processing prior to and/or after the etch process. This processing can be performed in the same chamber or in one or more separate processing chambers. In some embodiments, the substrate is moved from the first chamber to a separate, second chamber for further processing. The substrate can be moved directly from the first chamber to the separate processing chamber, or it can be moved from the first chamber to one or more transfer chambers, and then moved to the desired separate processing chamber. Accordingly, the processing apparatus may comprise multiple chambers in communication with a transfer station. An apparatus of this sort may be referred to as a “cluster tool” or “clustered system”, and the like.

Generally, a cluster tool is a modular system comprising multiple chambers which perform various functions including substrate center-finding and orientation, degassing, annealing, deposition and/or etching. According to one or more embodiments, a cluster tool includes at least a first chamber and a central transfer chamber. The central transfer chamber may house a robot that can shuttle substrates between and among processing chambers and load lock chambers. The transfer chamber is typically maintained at a vacuum condition and provides an intermediate stage for shuttling substrates from one chamber to another and/or to a load lock chamber positioned at a front end of the cluster tool. Two well-known cluster tools which may be adapted for the present invention are the Centura® and the Endura®, both available from Applied Materials, Inc., of Santa Clara, Calif. The details of one such staged-vacuum substrate processing apparatus is disclosed in U.S. Pat. No. 5,186,718, entitled “Staged-Vacuum Wafer Processing Apparatus and Method,” Tepman et al., issued on Feb. 16, 1993. However, the exact arrangement and combination of chambers may be altered for purposes of performing specific steps of a process as described herein. Other processing chambers which may be used include, but are not limited to, cyclical layer deposition (CLD), atomic layer deposition (ALD), chemical vapor deposition (CVD), physical vapor deposition (PVD), etch, pre-clean, chemical clean, thermal treatment such as RTP, plasma nitridation, degas, orientation, hydroxylation and other substrate processes. By carrying out processes in a chamber on a cluster tool, surface contamination of the substrate with atmospheric impurities can be avoided without oxidation prior to depositing any subsequent film.

According to one or more embodiments, the substrate is continuously under vacuum or “load lock” conditions, and is not exposed to ambient air when being moved from one chamber to the next. The transfer chambers are thus under vacuum and are “pumped down” under vacuum pressure. Inert gases may be present in the processing chambers or the transfer chambers. In some embodiments, an inert gas is used as a purge gas to remove some or all of the reactants after forming the silicon layer on the surface of the substrate. According to one or more embodiments, a purge gas is injected at the exit of the deposition chamber to prevent reactants from moving from the deposition chamber to the transfer chamber and/or additional processing chamber. Thus, the flow of inert gas forms a curtain at the exit of the chamber.

The substrate can be processed in single substrate deposition chambers, where a single substrate is loaded, processed and unloaded before another substrate is processed. The substrate can also be processed in a continuous manner, like a conveyer system, in which multiple substrate are individually loaded into a first part of the chamber, move through the chamber and are unloaded from a second part of the chamber. The shape of the chamber and associated conveyer system can form a straight path or curved path. Additionally, the processing chamber may be a carousel in which multiple substrates are moved about a central axis and are exposed to deposition, etch, annealing, cleaning, etc. processes throughout the carousel path.

During processing, the substrate can be heated or cooled. Such heating or cooling can be accomplished by any suitable means including, but not limited to, changing the temperature of the substrate support and flowing heated or cooled gases to the substrate surface. In some embodiments, the substrate support includes a heater/cooler which can be controlled to change the substrate temperature conductively. In one or more embodiments, the gases (either reactive gases or inert gases) being employed are heated or cooled to locally change the substrate temperature. In some embodiments, a heater/cooler is positioned within the chamber adjacent the substrate surface to convectively change the substrate temperature.

The substrate can also be stationary or rotated during processing. A rotating substrate can be rotated continuously or in discreet steps. For example, a substrate may be rotated throughout the entire process, or the substrate can be rotated by a small amount between exposure to different reactive or purge gases. Rotating the substrate during processing (either continuously or in steps) may help produce a more uniform deposition or etch by minimizing the effect of, for example, local variability in gas flow geometries.

### EXAMPLE

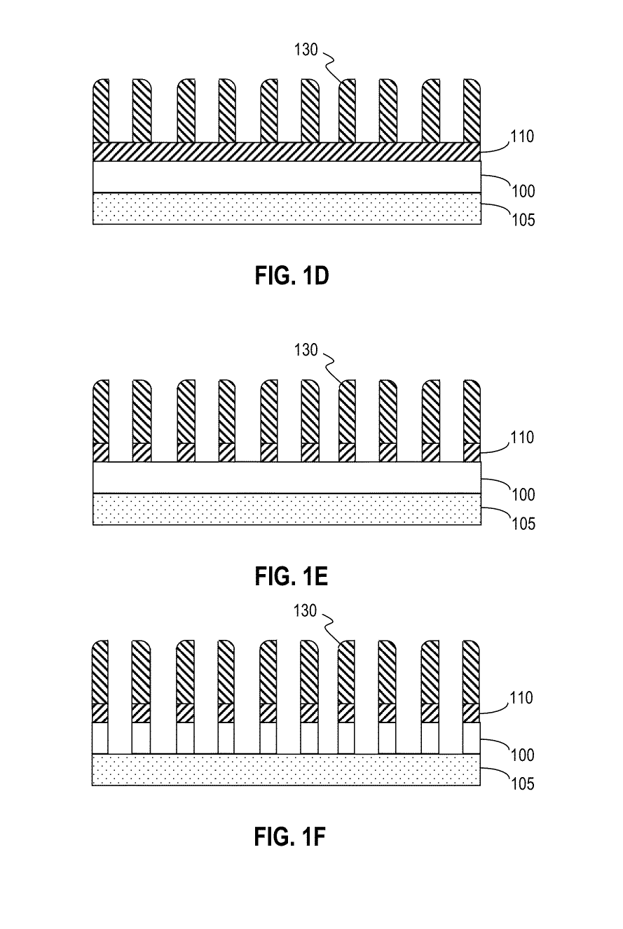

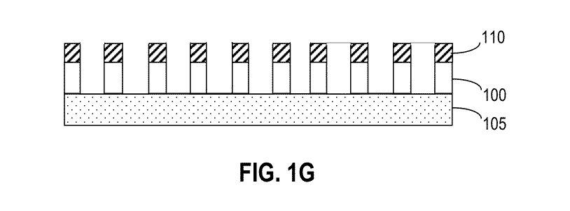

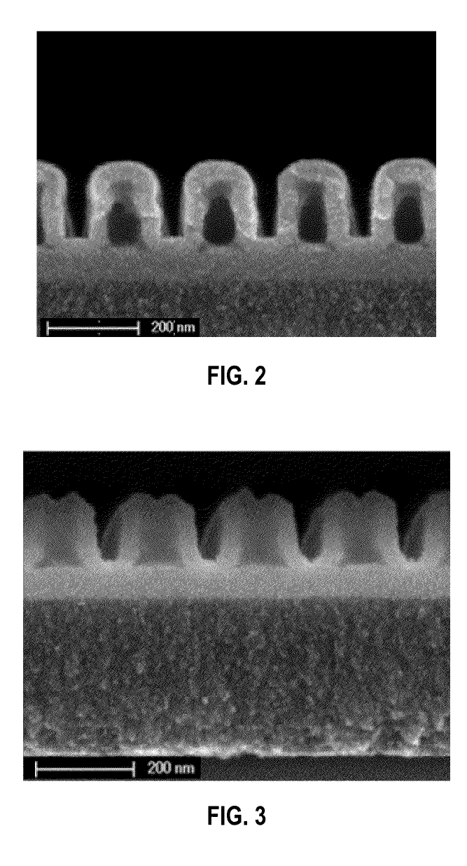

HfBₓO_{y} spacer material was deposited over a film stack comprising, in order from top to bottom, 1200 A of patterned photoresist, 400 A DARC material, 2000 A of Advanced Patterning Film™ (APF) and silicon. FIG. 2 shows the deposited HfBₓO_{y} spacer material overlying the rest of the film stack. The HfBₓO_{y} spacer material was etched in 10 mTorr plasma with a gas mixture of 200 sccm Ar and 150 sccm BCl₃. The plasma source power was 500 W and wafer bias power was 80 W. After 30 seconds of HfBₓO_{y} etch, the horizontal HfBₓO_{y} hardmask was removed, and the photoresist core was exposed. The vertical HfBₓO_{y} was remained as spacer. FIG. 3 shows the etched HfBₓO_{y} film, now forming spacer. The photoresist cores were then stripped, as shown in FIG. 4. As also shown in FIG. 4, the spacers were able to maintain their shape after the photoresist cores were stripped.

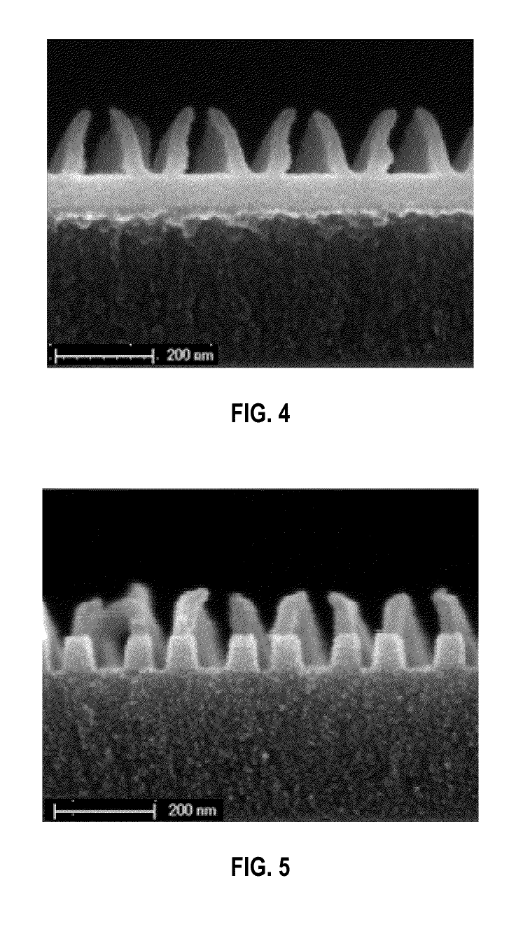

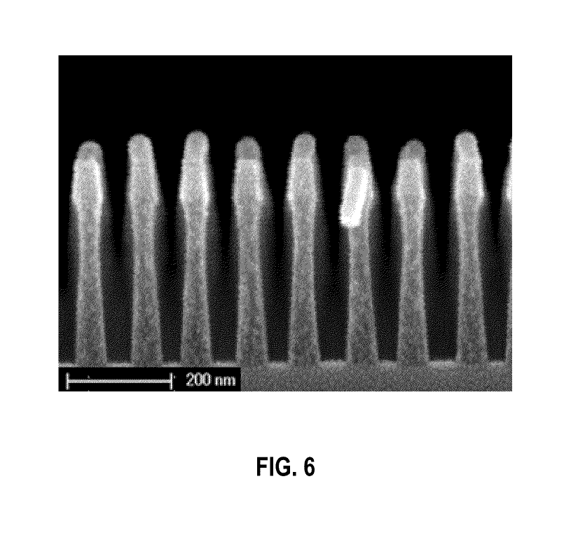

The DARC and APF® layers were then etched using the HfBₓO_{y} spacer material as an etch mask. FIGS. 5 and 6 demonstrate that the pattern formed by the HfBₓO_{y} spacers was successfully transferred to the DARC and APF® layers, respectively. In particular, FIG. 6 shows that there was still a significant amount of HfBxOy spacer remaining after the APF® etch, indicating HfBₓO_{y} has very high etch selectivity to DARC and APF® layers.

Reference throughout this specification to “one embodiment,” “certain embodiments,” “one or more embodiments” or “an embodiment” means that a particular feature, structure, material, or characteristic described in connection with the embodiment is included in at least one embodiment of the invention. Thus, the appearances of the phrases such as “in one or more embodiments,” “in certain embodiments,” “in one embodiment” or “in an embodiment” in various places throughout this specification are not necessarily referring to the same embodiment of the invention. Furthermore, the particular features, structures, materials, or characteristics may be combined in any suitable manner in one or more embodiments.

Although the invention herein has been described with reference to particular embodiments, it is to be understood that these embodiments are merely illustrative of the principles and applications of the present invention. It will be apparent to those skilled in the art that various modifications and variations can be made to the method and apparatus of the present invention without departing from the spirit and scope of the invention. Thus, it is intended that the present invention include modifications and variations that are within the scope of the appended claims and their equivalents.

What is claimed is:

1. A method of etching a film on a substrate, the method comprising:
exposing at least part of a film on a substrate, the film comprising one or more of HfO₂, HfBₓO_{y}, ZrO₂, ZrBₓO_{y}, to a plasma comprising BCl₃ and argon to etch away said at least part of the film.

2. The method of claim 1, wherein the substrate has a temperature of about 20 to about 200° C. during exposure of the substrate to the plasma.

3. The method of claim 1, wherein the argon is flowed at a rate of about 200 sccm.

4. The method of claim 3, wherein the BCl₃ is flowed at a rate ranging from about 50 sccm to about 150 sccm.

5. The method of claim 4, wherein said at least part of the film is etched at a rate of from about 400 A/min to about 700 A/min.

6. The method of claim 1, wherein the plasma is generated at a power of about 300 W to about 1500 W.

7. The method of claim 1, wherein the substrate has a wafer bias power of from about 50 to about 200 W.

8. The method of claim 1, wherein said at least part of the film is exposed to the Ar and BCl₃ simultaneously.

9. The method of claim 1, further comprising exposing said at least part of the film to Cl₂.

10. The method of claim 1, wherein the method occurs in a chamber, and the chamber has a pressure of about 5 mTorr to about 20 mTorr.

11. A method of patterning a substrate, the method comprising:
depositing a film comprising hafnium or zirconium on a patterned layer on a substrate;
anisotropically etching the film comprising hafnium or zirconium to partially expose the patterned layer, wherein anisotropically etching the film comprises exposing at least part of the film on a substrate to a plasma comprising BCl₃ and argon;
plasma etching the patterned layer to substantially remove the patterned layer from the substrate and provide spacers comprising the film;
patterning the substrate using the spacers to provide a patterned substrate; and
substantially removing the spacers.

12. The method of claim 11, wherein the film comprises HfO₂, HfBₓO_{y}, ZrO₂ or ZrBₓO_{y}.

13. The method of claim 11, wherein the patterned layer is a patterned photoresist.

14. The method of claim 13, wherein plasma etching the patterned photoresist comprises exposing the patterned photoresist to a second plasma comprising oxygen.

15. The method of claim 11, wherein the spacers are removed using dilute HF or a dry strip process.

16. The method of claim 11, wherein the substrate comprises a dielectric anti-reflection coating.

17. The method of claim 11, wherein the substrate has a temperature of about 10 to about 200° C. during the anisotropic etch.

18. The method of claim 11, wherein the plasma is flowed at a rate ranging from about 50 sccm to about 150 sccm and the second plasma is flowed at a rate of about 200 sccm.

19. A method of patterning a substrate, the method comprising:
forming a patterned photoresist on a substrate, wherein the substrate comprises silicon, an underlayer comprising a carbon-based polymeric layer or an amorphous carbon-based layer on the silicon, and a dielectric anti-reflective coating on the underlayer;
depositing a film comprising HfO₂, HfBₓO_{y}, ZrO₂ or ZrBₓO_{y} on the patterned photo resist and substrate;
anisotropically etching the film comprising hafnium or zirconium to partially expose the patterned photoresist, wherein anisotropically etching the film comprises exposing at least part of the film on a substrate to a plasma comprising BCl₃ and argon, and wherein the substrate has a temperature of about 20 to about 200° C. during the anisotropic etch;
plasma etching the patterned photoresist to substantially remove the patterned photo resist from the substrate and exposing more of the dielectric anti-reflective coating, and to provide spacers comprising the film;
removing the exposed parts of the dielectric anti-reflective coating to expose at least a part of the underlayer and provide dielectric anti-reflective coating only under the spacers;
removing the exposed part of the underlayer to expose at least a portion of the substrate and provide underlayer only under the spacers and dielectric anti-reflective coating; and
removing the spacers comprising the film.

20. The method of claim 19, further comprising patterning the exposed substrate.
